(19) United States
(12) Patent Application Publication
(10) Pub. No.: US 2026/0164715 A1
(43) Pub. Date: Jun. 11, 2026

(54) STACKED FIELD-EFFECT TRANSISTOR (FET) WITHOUT PLACEHOLDER

(71) Applicant: INTERNATIONAL BUSINESS MACHINES CORPORATION, ARMONK, NY (US)

(72) Inventors: Sarah Nahar Chowdhury, Guilderland, NY (US); Ruilong Xie, Niskayuna, NY (US); Shay Reboh, Guilderland, NY (US); Chen Zhang, Santa Clara, CA (US); Tenko Yamashita, Schenectady, NY (US); Kisik Choi, Watervliet, NY (US); Junli Wang, Slingerlands, NY (US)

(21) Appl. No.: 18/975,241

(22) Filed: Dec. 10, 2024

(51) Int. Cl. H10D 30/67; H10D 30/00; H10D 30/01; H10D 62/10; H10D 84/01; H10D 84/85

(52) U.S. Cl. CPC H10D 30/6729; H10D 30/0191; H10D 30/502; H10D 30/6735; H10D 62/121; H10D 84/0167; H10D 84/0186; H10D 84/851

(57) ABSTRACT

Embodiments of the invention include a method for fabricating a semiconductor device and the resulting structure. A p-channel field-effect transistor (pFET) having a source/drain region is formed, where: a bottom surface of the source/drain region is of a depth lower than a bottom surface of a gate region; and the source/drain region comprises a silicon germanium alloy doped with boron; An n-channel field-effect transistor (nFET) is formed. A via is formed, where the via has a top surface above a top surface of the nFET. The semiconductor structure is flipped. A substrate is selectively removed respective to the source/drain region. A backside interlayer dielectric (ILD) is formed, where the backside ILD is of a different material than a shallow trench isolation layer. A backside contact is formed, where the backside contact contacts the source/drain region and the via.

### BACKGROUND

The present invention relates generally to the field of semiconductor devices and fabrication, and more particularly to stacked field-effect transistors (FETs).

A field-effect transistor (FET) is a type of transistor that uses an electric field to control the flow of current in a semiconductor. A FET includes three terminals, a source, gate, and drain. FETs control the flow of current by the application of a voltage to the gate, which in turn alters conductivity between the drain and source.

A power delivery network is designed to provide power supply and reference voltage to active devices. Traditionally, this is realized as a network of low-resistive metal wires fabricated through back end of line (BEOL) processing on the frontside of a wafer. A backside power delivery network (BPDN) moves the power distribution network to the backside of the wafer and enables direct power delivery through wider, less resistive metal lines, without electrons needing to travel through a complex BEOL stack.

A buried power rail (BPR) or backside power rail (BSPR) is a metal line construct buried below transistors, partially within a substrate and partially within a shallow trench isolation (STI) layer. Such a power rail takes the role of power rails that have traditionally been implemented at the BEOL level.

### SUMMARY

Embodiments of the invention include a semiconductor structure that includes a first field-effect transistor (FET) having a first source/drain region, where a bottom surface of the first source/drain region is of a depth lower than a bottom surface of a gate region. A second FET is stacked above the first FET. A first via has a top surface above a top surface of the second FET. A backside contact contacts the first source/drain region and the first via.

Embodiments of the invention also include a semiconductor structure that includes a bottom a field-effect transistor (FET) having a source/drain region and a top FET, where: a bottom surface of the source/drain region is of a depth lower than a bottom surface of a gate region; and the source/drain region includes epitaxially grown silicon with added dopants. A via has a top surface above a top surface of the top FET. A backside contact contacts the source/drain region and the via.

Embodiments of the invention include a method for fabricating a semiconductor device. The method includes forming a p-channel field-effect transistor (pFET) having a source/drain region, where: a bottom surface of the source/drain region is of a depth lower than a bottom surface of a gate region; and the source/drain region includes a silicon germanium alloy doped with boron. The method can also include forming an n-channel field-effect transistor (nFET). The method can also include forming a via, where the via has a top surface above a top surface of the nFET. The method can also include flipping the semiconductor structure. The method can also include selectively removing a substrate respective to the source/drain region. The method can also include forming a backside interlayer dielectric (ILD), where the backside ILD is of a different material than a shallow trench isolation layer. The method can also include forming a backside contact, where the backside contact contacts the source/drain region and the via.

### BRIEF DESCRIPTION OF THE DRAWINGS

FIG. 1 depicts a top-down simplified view of a device, the device including gates and active device areas of each stacked field-effect transistor (FET) structure, in accordance with an embodiment of the present invention.

FIG. 2A depicts a cross-sectional view, along section line A of FIG. 1, FIG. 2B depicts a cross-sectional view, along section line B of FIG. 1, and FIG. 2C depicts a cross-sectional view, along section line C of FIG. 1, of a device upon which embodiments of the invention can be fabricated, in accordance with an embodiment of the present invention.

FIG. 3A depicts a cross-sectional view, along section line A of FIG. 1, FIG. 3B depicts a cross-sectional view, along section line B of FIG. 1, and FIG. 3C depicts a cross-sectional view, along section line C of FIG. 1, of a process of forming a dielectric spacer material layer, forming recesses within a semiconductor material stack, recessing a sacrificial semiconductor material layer, and forming inner spacers, in accordance with an embodiment of the present invention.

FIG. 4A depicts a cross-sectional view, along section line A of FIG. 1, FIG. 4B depicts a cross-sectional view, along section line B of FIG. 1, and FIG. 4C depicts a cross-sectional view, along section line C of FIG. 1, of a process of forming a bottom source/drain region, top source/drain region, and interlayer dielectric (ILD) material, in accordance with an embodiment of the present invention.

FIG. 5A depicts a cross-sectional view, along section line A of FIG. 1, FIG. 5B depicts a cross-sectional view, along section line B of FIG. 1, and FIG. 5C depicts a cross-sectional view, along section line C of FIG. 1, of a process of forming gate cuts, removing the sacrificial semiconductor material layer and sacrificial gate structure, and forming a replacement gate, in accordance with an embodiment of the present invention.

FIG. 6A depicts a cross-sectional view, along section line A of FIG. 1, FIG. 6B depicts a cross-sectional view, along section line B of FIG. 1, and FIG. 6C depicts a cross-sectional view, along section line C of FIG. 1, of a process of forming contacts/vias and via liners, in accordance with an embodiment of the present invention.

FIG. 7A depicts a cross-sectional view, along section line A of FIG. 1, FIG. 7B depicts a cross-sectional view, along section line B of FIG. 1, and FIG. 7C depicts a cross-sectional view, along section line C of FIG. 1, of a process of forming frontside power rales in additional ILD material and a back end of line (BEOL) interconnect and bonding the device to a carrier wafer, in accordance with an embodiment of the present invention.

FIG. 8A depicts a cross-sectional view, along section line A of FIG. 1, FIG. 8B depicts a cross-sectional view, along section line B of FIG. 1, and FIG. 8C depicts a cross-sectional view, along section line C of FIG. 1, of a process of removing a semiconductor substrate, in accordance with an embodiment of the present invention.

FIG. 9A depicts a cross-sectional view, along section line A of FIG. 1, FIG. 9B depicts a cross-sectional view, along section line B of FIG. 1, and FIG. 9C depicts a cross-sectional view, along section line C of FIG. 1, of a process of removing an etch stop layer and a semiconductor layer, in accordance with an embodiment of the present invention.

FIG. 10A depicts a cross-sectional view, along section line A of FIG. 1, FIG. 10B depicts a cross-sectional view, along section line B of FIG. 1, and FIG. 10C depicts a cross-sectional view, along section line C of FIG. 1, of a process of forming a backside ILD, in accordance with an embodiment of the present invention.

FIG. 11A depicts a cross-sectional view, along section line A of FIG. 1, FIG. 11B depicts a cross-sectional view, along section line B of FIG. 1, and FIG. 11C depicts a cross-sectional view, along section line C of FIG. 1, of a process of forming backside contact trenches, in accordance with an embodiment of the present invention.

FIG. 12A depicts a cross-sectional view, along section line A of FIG. 1, FIG. 12B depicts a cross-sectional view, along section line B of FIG. 1, and FIG. 12C depicts a cross-sectional view, along section line C of FIG. 1, of a process of selectively removing exposed portions of a shallow trench isolation (STI) layer and via liners, in accordance with an embodiment of the present invention.

FIG. 13A depicts a cross-sectional view, along section line A of FIG. 1, FIG. 13B depicts a cross-sectional view, along section line B of FIG. 1, and FIG. 13C depicts a cross-sectional view, along section line C of FIG. 1, of a process of forming backside contacts, in accordance with an embodiment of the present invention.

FIG. 14A depicts a cross-sectional view, along section line A of FIG. 1, FIG. 14B depicts a cross-sectional view, along section line B of FIG. 1, and FIG. 14C depicts a cross-sectional view, along section line C of FIG. 1, of a process of forming additional backside ILD, backside power rails, and a backside power delivery network (BSPDN), in accordance with an embodiment of the present invention.

### DETAILED DESCRIPTION

Embodiments of the present invention recognize that direct backside contact(s) are necessary for I-shaped monolithic stacked field-effect transistors (FETs). Embodiments of the present invention further recognize that utilizing a placeholder-based approach for a direct backside contact and monolithic stacked field-effect transistor (FET) results in too high of an aspect ratio.

Embodiments of the present invention recognize that one approach to addressing some of the described key challenges is to provide an I-shaped monolithic stacked FET without a placeholder in order to lower the aspect ratio. Embodiments of the present invention recognize that an approach without a placeholder can be realized by utilizing, for example, a bottom source/drain region with a p-type dopant. Such an approach alleviates concerns of bottom source/drain region damage, even without a placeholder.

Embodiments of the present invention describe an approach for fabricating a semiconductor device, the approach including forming a bottom p-channel field-effect transistor (pFET) device with a bottom source/drain region comprising a silicon germanium alloy that is doped with a p-type dopant such as, for example, boron. In some embodiments, the bottom source/drain region has a bottom surface deeper than a bottom surface of the gate. For example, the bottom surface of the bottom source/drain region may be of a depth similar to that of the shallow trench isolation (STI) layer. Embodiments of the present invention further describe forming a top n-channel field-effect transistor (nFET) device. Embodiments of the present invention further describe forming middle-of-line (MOL) contacts including deep via (RV) connects to the top source/drain region by an upper contact layer and shallower RVs with a bottom surface similar to that of a bottom surface of the bottom source/drain region. Embodiments of the present invention further describe forming back end of line a (BEOL) interconnect and bonding the device to a carrier wafer. Embodiments of the present invention further describe flipping the device and removing a substrate selective to the bottom source drain region comprising the silicon germanium alloy that is doped with a p-type dopant such as, for example, boron. Embodiments of the present invention further describe forming a backside interlayer dielectric (ILD) material with a different material than the STI. Embodiments of the present invention further describe forming a backside contacts, including contacts (i) to connect to bottom source drain region(s) to backside power and (ii) to connect a shallower RV to bottom source/drain region(s) such that the respective bottom source/drain region is electrically connected to frontside power.

Embodiments of the present invention describe a resulting semiconductor structure that includes at least one transistor stacking over another transistor, wherein the bottom transistor is pFET with a SiGe based source/drain region that is deeper than the gate. Embodiments of the present invention may further describe a resulting semiconductor structure that includes a backside contact that connects to the pFET source/drain region, partially wraps around a sidewall of the bottom source/drain region, and connects to a deep via. Embodiments of the present invention may further describe that the deep via connected to the backside contact is shorter compared to another deep via connected to a frontside contact. Embodiments of the present invention may further describe that the shorter deep via electrically connects the bottom source/drain region to a frontside interconnect and that the deep via electrically connects the top source/drain region to a backside interconnect. Embodiments of the present invention may further describe that the deep via has a dielectric liner (RV liner). Embodiments of the present invention may further describe that a backside ILD is of a different material than the RV liner or the STI.

According to an aspect of the invention, there is provided a semiconductor structure that includes a first field-effect transistor (FET) having a first source/drain region, where a bottom surface of the first source/drain region is of a depth lower than a bottom surface of a gate region, a second FET stacked above the first FET, a first via, where the first via has a top surface above a top surface of the second FET, and a backside contact contacting the first source/drain region and the first via. This can serve to allow for an I-shaped monolithic stacked FET that has a lower aspect ration compared to fabrication approaches that utilize a placeholder.

In embodiments, the first source/drain region comprises a silicon germanium alloy doped with a p-type dopant. This can serve to prevent damage to the first source/drain region during fabrication, without the need for a placeholder.

In embodiments, the p-type dopant is boron. This can serve to further prevent damage to the first source/drain region during fabrication, without the need for a placeholder.

In embodiments, there is further provided a first frontside contact contacting a second source/drain region of the second FET and a second via contacting the first frontside contact, where the second via has a bottom surface below the bottom surface of the first source/drain region. This can serve to allow for the second source/drain region to electrically contact backside power.

In embodiments, the first via is shorter than the second via. This can serve to align a bottom surface of the first via with a bottom surface of the first source/drain region, for subsequent electrical connection via a backside contact.

In embodiments, the first source/drain region is electrically connected to a BEOL interconnect. This can serve to provide frontside power to the first source/drain region, despite being beneath the second source/drain region.

In embodiments, the second source/drain region is electrically connected to a backside interconnect. This can server to provide backside power to the second source/drain region, despite being above the first source/drain region.

In embodiments, the first via has a dielectric liner. This can serve to prevent a short between the first via and nearby conductive elements.

In embodiments, there is further provided a backside interlayer dielectric (ILD), wherein the backside ILD is of a material different than: (i) the dielectric liner and (ii) a shallow trench isolation layer. This can serve to allow for selective removal of the backside ILD with respect to dielectric liner and the shallow trench isolation layer during fabrication processes (e.g., backside contact trench formation.

In embodiments, the shallow trench isolation layer has a height between fifteen and thirty nanometers. This can serve to allow for a shallow trench isolation layer and a nanosheet recess depth that is similar to the shallow trench isolation layer depth for subsequent fabrication of the first source/drain region.

In embodiments, the second source/drain region comprises a silicon alloy that is doped with an n-type dopant. This can serve to allow for a the second FET to be an nFET while the first FET is a pFET.

In embodiments, the n-type dopant is phosphorous. This can serve to allow for selective removal of ILD material during contact trench formation while limiting damage to the second source/drain region.

In embodiments, there is further provided a carrier wafer contacting the BEOL interconnect. This can serve to enable flipping of the device during fabrication processes.

In embodiments, the gate region wraps around nanosheet stacks of semiconductor channel material layers present within each of the first FET and the second FET. This can serve to create a gate all around device where a plurality of nanosheet channels are completely surrounded by a functional date structure.

In embodiments, the gate region is electrically connected to the BEOL interconnect through a second frontside contact. This can serve to provide power to the gate region.

In embodiments, there is further provided an inner spacer layer contacting the gate region and a selection from the group of: (i) the first source/drain region and (ii) the second source/drain region. This can serve to allow for the formation of the gate region during fabrication.

According to an aspect of the invention, there is provided a semiconductor structure that includes a bottom a field-effect transistor (FET) having a source/drain region, where: a bottom surface of the source/drain region is of a depth lower than a bottom surface of a gate region and the source/drain region comprises epitaxially grown silicon with added dopants, a top FET, a via having a top surface above a top surface of the top FET, and a backside contact contacting the source/drain region and the via. This can serve to allow for an I-shaped monolithic stacked FET that has a lower aspect ration compared to fabrication approaches that utilize a placeholder.

In embodiments, the source/drain region is electrically connected to a BEOL interconnect. This can serve to provide frontside power to the first source/drain region, despite being beneath the second source/drain region.

In embodiments, there is further provided a frontside contact contacting a second source/drain region of the top FET and a second via contacting the frontside contact, where the second via has a bottom surface below the bottom surface of the source/drain region. This can serve to allow for the second source/drain region to electrically contact backside power.

According to an aspect of the invention, there is provided a method of forming a semiconductor structure that includes forming a p-channel field-effect transistor (pFET) having a source/drain region, where: a bottom surface of the source/drain region is of a depth lower than a bottom surface of a gate region; and the source/drain region comprises a silicon germanium alloy doped with boron. The method may also include forming an n-channel field-effect transistor (nFET). The method may also include forming a via, where the via has a top surface above a top surface of the nFET. The method may also include flipping the semiconductor structure. The method may also include selectively removing a substrate respective to the source/drain region. The method may also include forming a backside interlayer dielectric (ILD), where the backside ILD is of a different material than a shallow trench isolation layer. The method may also include forming a backside contact, where the backside contact contacts the source/drain region and the via.

This can serve to allow for an I-shaped monolithic stacked FET that has a lower aspect ration compared to fabrication approaches that utilize a placeholder.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Each reference number may refer to an item individually or collectively as a group. For example, bottom source/drain region 410 may refer to a single bottom source/drain region 410 or multiple bottom source/drain regions 410.

The present invention will now be described in detail with reference to the Figures.

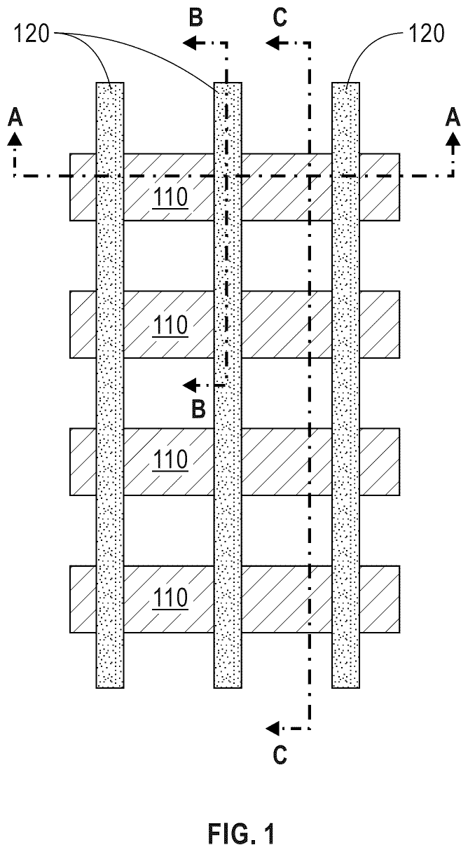

FIG. 1 is a simplified depiction of the device and is provided primarily to establish a frame of reference for the presence of the cross-sectional views of the other Figures. Accordingly, many objects and features that are present in the cross-sectional views are not depicted in FIG. 1. Further, FIG. 1 is a top view. FIG. 1 generally shows the location of the gates 120 and active device area (RX) 110 of each stacked field-effect transistor (FET) structure.

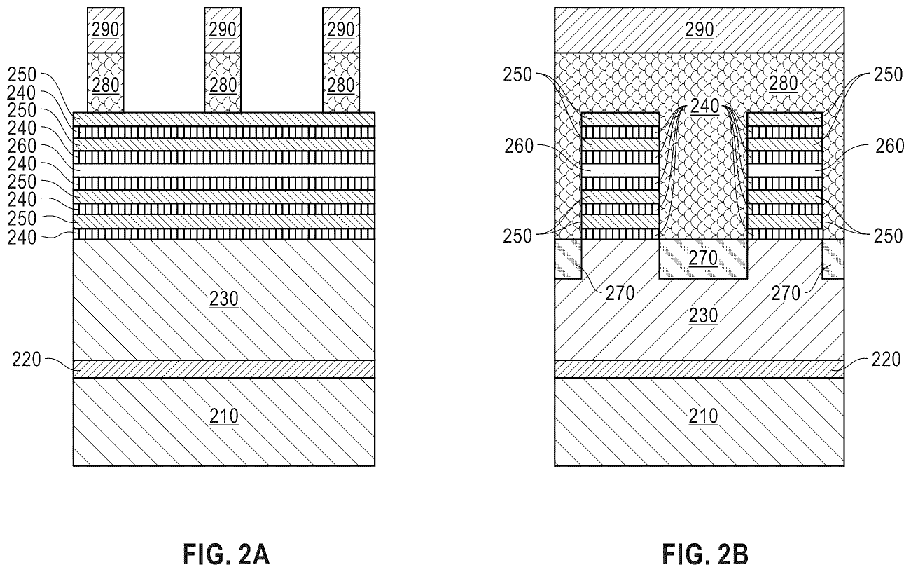

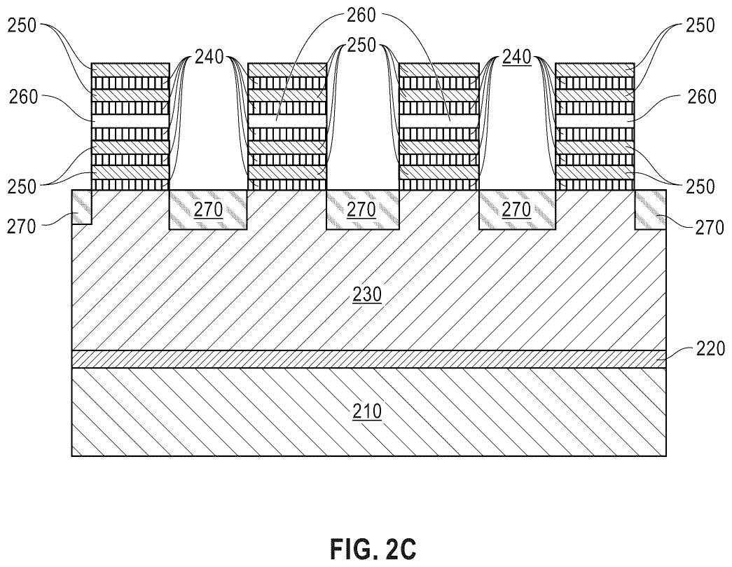

FIG. 2A depicts a cross-sectional view, of a device at an early stage in the method of forming the device, along section line A of FIG. 1, FIG. 2B depicts a cross-sectional view along section line B of FIG. 1, and FIG. 2C depicts a cross-sectional view along section line C of FIG. 1, in accordance with an embodiment of the present invention.

The semiconductor structure of FIGS. 2A-2C includes a semiconductor substrate with an etch stop layer, two Si/SiGe stacks separated by a middle sacrificial layer, a dummy gate, and a hardmask upon which embodiments of the invention can be fabricated.

Semiconductor substrate 210 may be composed of a silicon containing material. Silicon containing materials include, but are not limited to, silicon, single crystal silicon, polycrystalline silicon, SiGe, single crystal SiGe, polycrystalline SiGe, or silicon doped with carbon (C), amorphous silicon, and combinations and multi-layers thereof. Semiconductor substrate 210 can also be composed of other semiconductor materials, such as germanium (Ge), and compound semiconductor substrates, such as type III/V semiconductor substrates, e.g., gallium arsenide (GaAs). In general, semiconductor substrate 210 is a smooth surface substrate. In some embodiments (not shown), semiconductor substrate 210 can be a partially processed complementary metal-oxide semiconductor (CMOS) integrated wafer with transistors and wiring levels or gate electrodes embedded beneath the surface.

Etch stop layer 220 is present above semiconductor substrate 210. Etch stop layer 220 acts as a layer used to define the structure thickness by stopping the etch when the etch stop layer is reached. Etch stop layer 220 may be composed of, for example, silicon dioxide or epitaxy SiGe.

Semiconductor layer 230 is present above etch stop layer 220. Semiconductor layer 230 may be composed of a silicon containing material such as the silicon containing materials discussed with respect to semiconductor substrate 210.

In the depicted embodiment, a semiconductor material stack (sacrificial semiconductor material layer 240, semiconductor channel material layer 250) is formed upon semiconductor layer 230. The semiconductor material stack includes vertically aligned alternating layers of sacrificial semiconductor material layer 240 and semiconductor channel material layer 250. The semiconductor material stack is sequentially formed upon the semiconductor layer 230. As mentioned above, the semiconductor material stack includes sacrificial semiconductor material layers 240 and semiconductor channel material layers 250, which alternate one atop the other. In FIGS. 2A-2C, and only by way of one example, the semiconductor material stack includes five layers of sacrificial semiconductor material layer 240 and four layers of semiconductor channel material layer 250. In some embodiments, an additional middle sacrificial layer 260 can be formed between the top and bottom FET, which will later be removed and replaced with a dielectric layer, also called middle dielectric isolation (MDI) 310. The middle sacrificial layer 260 may be, for example, a silicon germanium allow that contains 55% germanium. The semiconductor material stacks that can be employed in embodiments of the present invention are not limited to the specific embodiment illustrated in FIGS. 2A-2C. Instead, the semiconductor material stack can include any number of sacrificial semiconductor material layers 240 and semiconductor channel material layers 250. The semiconductor material stack is used to provide a gate-all-around device that includes vertically stacked semiconductor channel material nanosheets for a pFET or nFET device. It should be noted that while the depicted embodiment uses a nanosheet device for the bottom device, the bottom device can be any kind of non-vertical or horizontal device, such as, for example, fin field-effect transistor (FinFET), planar FET, nanowire, or extremely-thin silicon-on-insulator (ETSOI).

Each sacrificial semiconductor material layer 240 is composed of a first semiconductor material which differs in composition from semiconductor layer 230, semiconductor channel material layer 250, and middle sacrificial layer 260. In one embodiment, each sacrificial semiconductor material layer 240 is composed of silicon germanium with Ge % 20% to 35%. In one embodiment, each sacrificial semiconductor material layer 240 is composed of silicon germanium with Ge % of 30%. The first semiconductor material, for each sacrificial semiconductor material layer 240, can be formed utilizing an epitaxial growth or deposition process.

Each semiconductor channel material layer 250 is composed of a second semiconductor material that has a different etch rate than the first semiconductor material of the sacrificial semiconductor material layers 240. The second semiconductor material of each semiconductor channel material layer 170 may be the same as, or different than, the semiconductor material of, at least, the upper portion of semiconductor layer 230. The second semiconductor material can be, for example, silicon. The second semiconductor material can be a SiGe alloy having a germanium content of twenty to fifty atomic percent germanium and the first semiconductor material is different than the second semiconductor material and the material that makes up middle sacrificial layer 260.

In one example, at least semiconductor layer 230 and each semiconductor channel material layer 250 is composed of Si or a III-V compound semiconductor, while each sacrificial semiconductor material layer 240 is composed of a SiGe alloy. The second semiconductor material, for each semiconductor channel material layer 250, can be formed utilizing an epitaxial growth or deposition process. The middle sacrificial layer 260 can be a different epitaxial growth layer, which is different than sacrificial semiconductor layer or semiconductor channel material layer 170 (e.g., SiGe with a higher Ge %, such as, for example, greater than or equal to 55%).

Semiconductor material stack (sacrificial semiconductor material layer 240, semiconductor channel material layer 250) can be formed by sequential epitaxial growth of alternating layers of the first semiconductor material and the second semiconductor material.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking. The epitaxial growth of the first and second semiconductor materials that provide the sacrificial semiconductor material layers 240 and the semiconductor channel material layers 250, respectively, can be performed utilizing any well-known precursor gas or gas mixture. Carrier gases like hydrogen, nitrogen, helium and argon can be used.

The sacrificial semiconductor material layers 240 that constitute the semiconductor material stack may have a thickness from five nanometers (nm) to twenty nm, while the semiconductor channel material layers 250 that constitute the semiconductor material stack may have a thickness from six nm to twelve nm. Each sacrificial semiconductor material layer 240 may have a thickness that is the same as, or different from, a thickness of each semiconductor channel material layer 250. In an embodiment, each sacrificial semiconductor material layer 240 has an identical thickness. In an embodiment, each semiconductor channel material layer 250 has an identical thickness.

Following epitaxial growth of the topmost layer of the semiconductor material stack (sacrificial semiconductor material layer 240, semiconductor channel material layer 250) a patterning process may be used to provide the semiconductor material stack. Patterning may be achieved by lithography and etching as is well known to those skilled in the art.

STI layer 270 may be formed by patterning a hardmask layer (not shown) using lithography and etching such that top surfaces of portions of semiconductor layer 230 are exposed corresponding to locations where trenches for STI layer 270 are desired. Accordingly, the hardmask layer is patterned such that semiconductor layer 230 is exposed at desired trench locations for STI layer 270. In some embodiments, STI layer 270 is of a depth of about fifteen to thirty nm.

Physically exposed portions of semiconductor layer 230 are removed. The removing of portions of semiconductor layer 230 can be performed utilizing an anisotropic etching process such as, for example, reactive ion etching (RIE). Portions of semiconductor layer 230 remain beneath the hardmask.

A sacrificial gate structure 280 may be formed. Each sacrificial gate structure is located on a first side and a second side of the semiconductor material stack (sacrificial semiconductor material layer 240, semiconductor channel material layer 250) and spans across a topmost surface of a portion of the semiconductor material stack (sacrificial semiconductor material layer 240, semiconductor channel material layer 250). Each sacrificial gate structure 280 thus straddles over a portion of the semiconductor material stack (sacrificial semiconductor material layer 240, semiconductor channel material layer 250).

Each sacrificial gate structure 280 may include a single sacrificial material portion or a stack of two or more sacrificial material portions (i.e., at least one sacrificial material portion). In one embodiment, the at least one sacrificial material portion comprises, from bottom to top, a sacrificial gate structure 280 portion and a sacrificial dielectric cap 290 portion. In some embodiments, the sacrificial dielectric cap 290 portion can be omitted and only a sacrificial gate structure 280 portion is formed. The at least one sacrificial material portion can be formed by forming a blanket layer (or layers) of a material (or various materials) and then patterning the material (or various materials) by lithography and an etch. In one embodiment, the at least one sacrificial material portion can be formed by first depositing a blanket layer of a sacrificial gate material. The sacrificial gate material can include any material including, for example, polysilicon, amorphous silicon, an elemental metal (e.g., tungsten, titanium, tantalum, aluminum, nickel, ruthenium, palladium and platinum), an alloy of at least two elemental metals or multilayered combinations thereof. The sacrificial gate structure 280 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

After forming the blanket layer of sacrificial gate material, a blanket layer of a sacrificial gate cap material can be formed. The sacrificial gate cap material may include a hardmask material such as, for example, silicon dioxide and/or silicon nitride. The sacrificial gate cap material can be formed by any suitable deposition process such as, for example, chemical vapor deposition (CVD) or plasma enhanced chemical vapor deposition (PECVD).

After providing the above mentioned sacrificial material stack (or any subset of the sacrificial materials), lithography and etching can be used to pattern the sacrificial material stack (or any subset of the sacrificial materials) and to provide the at least one sacrificial gate structure. The remaining portions of the sacrificial gate material constitute a sacrificial gate structure 280 portion, and the remaining portions of the sacrificial dielectric cap material constitute a sacrificial dielectric cap 290 portion.

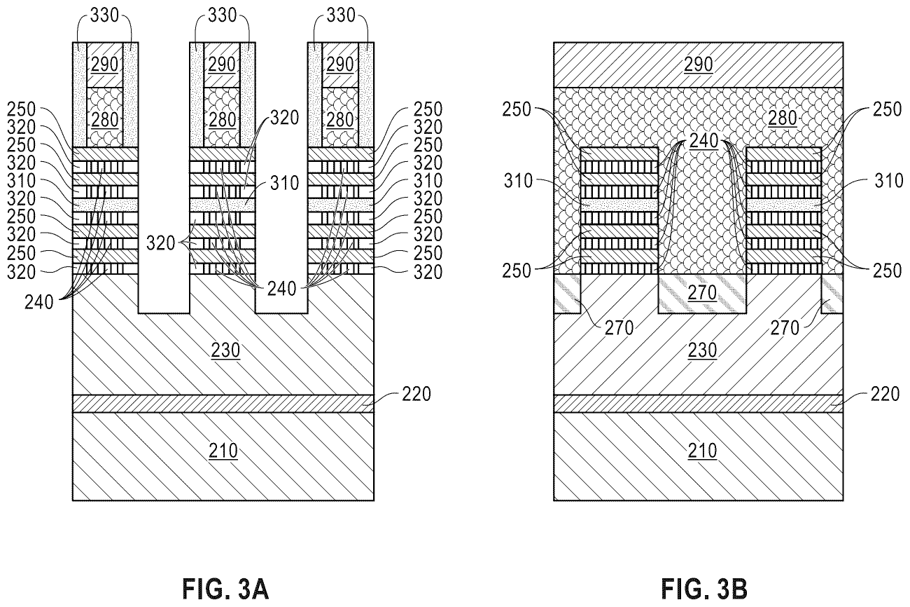

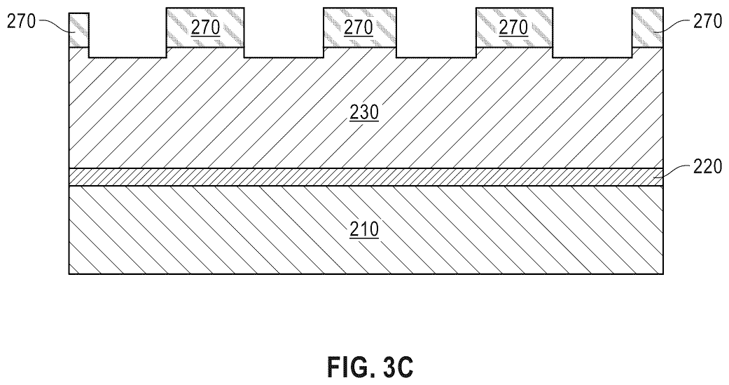

FIG. 3A depicts a cross-sectional view, of fabrication steps, along section line A of FIG. 1, FIG. 3B depicts a cross-sectional view along section line B of FIG. 1, and FIG. 3C depicts a cross-sectional view along section line C of FIG. 1. FIGS. 3A-3C depict the formation of dielectric spacer material layer 330, the formation of recesses within the semiconductor material stack to create nanosheet stacks, the recessing of sacrificial semiconductor material layer 240, and the formation of inner spacers 320.

After providing the sacrificial gate structure 280 and the sacrificial dielectric cap 290, middle sacrificial layer 260 is selectively removed respective to semiconductor channel material layer 250 and sacrificial semiconductor material layer 240, followed by filling the cavities with MDI 310.

After, dielectric spacer material layer 330 can be formed on exposed surfaces of each sacrificial gate structure 280 and each sacrificial dielectric cap 290. The dielectric spacer material layer 330 can be formed by first providing a dielectric spacer material and then etching the dielectric spacer material. One example of a dielectric spacer material that may be employed in the present application is silicon nitride. In general, the dielectric spacer material layer 330 comprises any dielectric spacer material, including, for example, a dielectric nitride, dielectric oxide, and/or dielectric oxynitride. More specifically, the dielectric spacer material layer 330 may be, for example, SiBCN, SiBN, SiOCN, SiON, SiCO, or SiC. In one example, the dielectric spacer material layer 330 is composed of a dielectric material such as SiO₂.

The dielectric spacer material that provides the dielectric spacer material layer 330 may be provided by a deposition process including, for example, ALD, chemical vapor deposition (CVD), plasma enhanced chemical vapor deposition (PECVD), or physical vapor deposition (PVD). The etch used to provide the dielectric spacer material layer may comprise a dry etching process such as, for example, reactive ion etching.

Recesses may be formed within the semiconductor material stack, creating the formation of nanosheet stacks of alternating nanosheets of sacrificial semiconductor material layers 240 and semiconductor channel material layers 250 that are under at least one sacrificial gate structure 280 and dielectric spacer material layer 330.

The nanosheet stack is formed by removing physically exposed portions of the semiconductor material stack (sacrificial semiconductor material layer 240, semiconductor channel material layer 250) and portions of semiconductor layer 230 that are not protected by the least one sacrificial gate structure 280 and the dielectric spacer material layer 330. In general, each recess may include the eventual location of bottom source/drain region 410, for the semiconductor device. In some embodiments, the recess is formed such that the recess is of a depth similar to the depth of STI layer 270.

The removing of the portions of the semiconductor material stack (sacrificial semiconductor material layer 240, semiconductor channel material layer 250) and the portions of semiconductor layer 230 not covered by the least one sacrificial gate structure 280 and the dielectric spacer material layer 330 can be performed utilizing an anisotropic etching process such as, for example, reactive ion etching (RIE). Portions of the semiconductor material stack (sacrificial semiconductor material layer 240, semiconductor channel material layer 250) remain beneath at least one sacrificial gate structure 280 and the dielectric spacer material layer 330. The remaining portion of the semiconductor material stack that is present beneath the at least one sacrificial gate structure 280 and the dielectric spacer material layer 330 is referred to as a nanosheet stack.

Each nanosheet stack includes alternating nanosheets of remaining portions of each sacrificial semiconductor material layer 240 and remaining portions of each semiconductor channel material layer 250. Each nanosheet (i.e., sacrificial semiconductor material layer 240 or semiconductor channel material layer 250) that constitutes the nanosheet stack has a thickness as mentioned above for the individual sacrificial semiconductor material layers 240 and semiconductor channel material layers 250, and a width from thirty nm to two hundred nm. In some embodiments, the sidewalls of each sacrificial semiconductor material layer 240 are vertically aligned to sidewalls of each semiconductor channel material layer 250, and the vertically aligned sidewalls of the nanosheet stack are vertically aligned to an outmost sidewall of the dielectric spacer material layer 330.

The sacrificial semiconductor material layer 240 is recessed and inner spacer 320 is formed. Each recessed sacrificial semiconductor material layer 240 has a width that is less than the original width of each sacrificial semiconductor material layer 240. The recessing of each sacrificial semiconductor material layer 240 provides a gap between each neighboring pair of semiconductor channel material layer 250 within a given nanosheet stack. The recessing of each sacrificial semiconductor material layer 240 may be performed utilizing a lateral etching process that is selective in removing physically exposed end portions of each sacrificial semiconductor material layer 240 relative to MDI 310 and each semiconductor channel material layer 250.

The additional dielectric spacer material that is added can be compositionally the same as the dielectric spacer material layer 330 mentioned above. In one example, the additional dielectric spacer material and the dielectric spacer material layer 330 are both composed of silicon nitride. For clarity, the additional dielectric spacer material and the dielectric spacer material layer 330 can now be collectively referred to as inner spacer 320. The inner spacer 320 is formed by a conformal dielectric liner deposition followed by isotropic etching back the deposited liner.

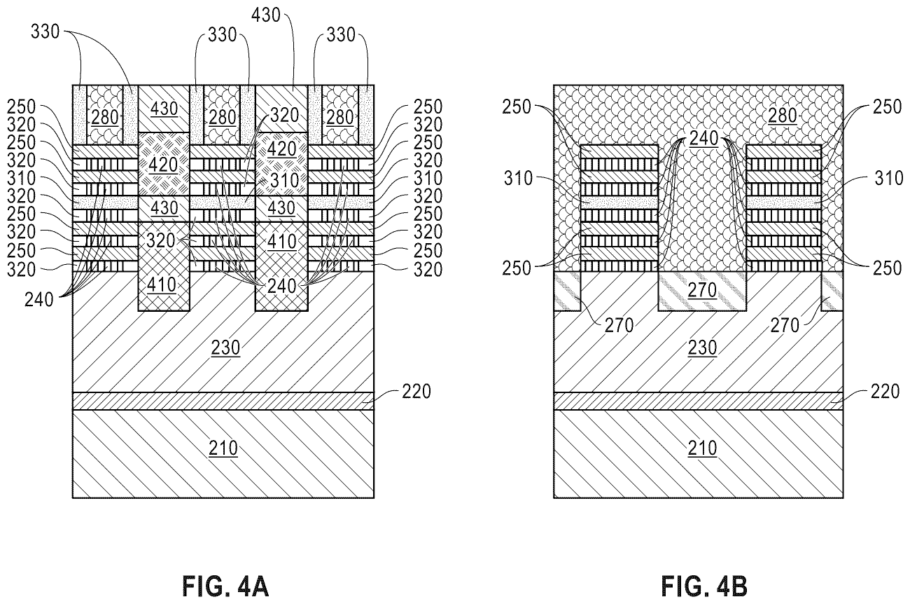

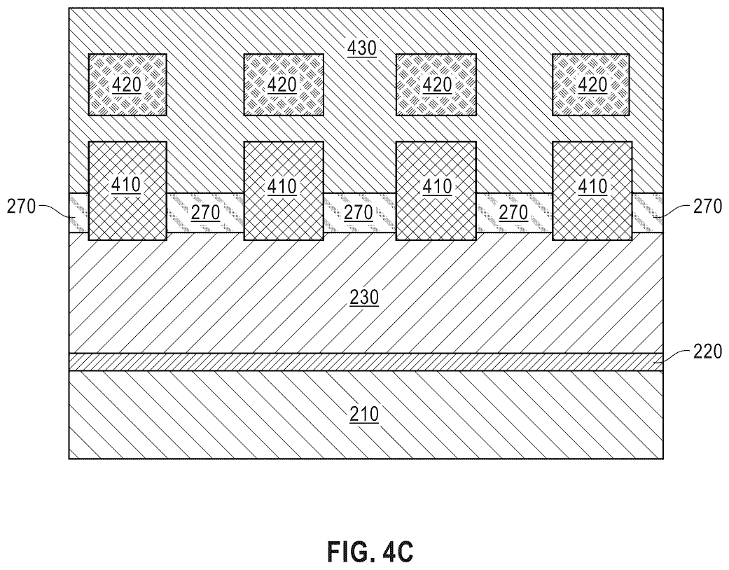

FIG. 4A depicts a cross-sectional view, of fabrication steps, along section line A of FIG. 1, FIG. 4B depicts a cross-sectional view along section line B of FIG. 1, and FIG. 4C depicts a cross-sectional view along section line C of FIG. 1. FIGS. 4A-4C depict the formation of bottom source/drain region 410, top source/drain region 420, and ILD material 430.

Bottom source/drain region 410 is formed by epitaxial growth of a semiconductor material on physically exposed sidewalls of each semiconductor channel material layer 250 below MDI 310 (a projective liner (not shown) can be formed over top channels of semiconductor channel material layer 250 above MDI 310 during bottom S/D epi growth). The bottom source/drain region 410 has a bottommost surface that directly contacts a topmost surface of semiconductor layer 230.

Each bottom source/drain region 410 includes a semiconductor material and a dopant. The semiconductor material that provides each bottom source/drain region 410 can be selected from one of the semiconductor materials mentioned above for the semiconductor layer 230. In some embodiments, the semiconductor material that provides each bottom source/drain region 410 may comprise a same semiconductor material as that which provides semiconductor channel material layer 250. In other embodiments, the semiconductor material that provides each bottom source/drain region 410 may comprise a different semiconductor material than that which provides semiconductor channel material layer 250. For example, the semiconductor material that provides each bottom source/drain region 410 may comprise a silicon germanium alloy, while semiconductor channel material layer 250 may comprise silicon.

The dopant that is present in each bottom source/drain region 410 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one embodiment, the dopant that can be present in each bottom source/drain region 410 can be introduced into the precursor gas that provides each bottom source/drain region 410. In another embodiment, the dopant can be introduced into an intrinsic semiconductor layer by utilizing one of ion implantation or gas phase doping. In one example, each bottom source/drain region 410 comprises a silicon germanium alloy that is doped with a p-type dopant such as, for example, boron. As mentioned above, each bottom source/drain region 410 is formed by an epitaxial growth (or deposition) process, as is defined above. In embodiments that include a silicon germanium alloy that is doped with a p-type dopant such as, for example, boron, embodiments of the present invention recognize that no placeholder is required.

ILD material 430 is formed above each bottom source/drain region 410. ILD material 430 may be composed of silicon dioxide, undoped silicate glass (USG), fluorosilicate glass (FSG), borophosphosilicate glass (BPSG), a spin-on low-κ dielectric layer, a chemical vapor deposition (CVD) low-κ dielectric layer or any combination thereof. The term “low-κ” as used throughout the present application denotes a dielectric material that has a dielectric constant of less than silicon dioxide. In another embodiment, a self-planarizing material such as a spin-on glass (SOG) or a spin-on low-κ dielectric material such as SiLK™ can be used as ILD material 430. The use of a self-planarizing dielectric material as ILD material 430 may avoid the need to perform a subsequent planarizing step.

In one embodiment, ILD material 430 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as ILD material 430, a planarization process or an etch back process follows the deposition of the dielectric material that provides ILD material 430, such that top channel layers (e.g., layers of semiconductor channel material layer 250 that are above MDI 310) are revealed and bottom source/drain region 410 are covered by ILD material 430.

Then, the top source/drain region 420 is formed by epitaxial growth of a semiconductor material on physically exposed sidewalls of each semiconductor channel material layer 250 of the top FET above MDI 310. In the depicted embodiment, the semiconductor material that provides the top source/drain region 420 grows laterally out from the sidewalls of each semiconductor channel material layer 250 of the top FET. The top source/drain region 420 has a bottommost surface that directly contacts a topmost surface of the ILD material 430 that is present atop the bottom source/drain region 410.

Each top source/drain region 420 includes a semiconductor material and a dopant. The semiconductor material that provides each top source/drain region 420 can be selected from one of the semiconductor materials mentioned above for the semiconductor layer 230. In some embodiments, the semiconductor material that provides each top source/drain region 420 may comprise a same semiconductor material as that which provides semiconductor channel material layer 250. In other embodiments, the semiconductor material that provides each top source/drain region 420 may comprise a different semiconductor material than that which provides semiconductor channel material layer 250. For example, the semiconductor material that provides each top source/drain region 420 may comprise a silicon germanium alloy, while semiconductor channel material layer 250 may comprise silicon.

The dopant that is present in each top source/drain region 420 can be either a p-type dopant or an n-type dopant. In one embodiment, the dopant that can be present in each top source/drain region 420 can be introduced into the precursor gas that provides each top source/drain region 420. In another embodiment, the dopant can be introduced into an intrinsic semiconductor layer by utilizing one of ion implantation or gas phase doping. In one example, each top source/drain region 420 comprises a silicon alloy that is doped with an n-type dopant such as, for example, phosphorus. As mentioned above, each top source/drain region 420 is formed by an epitaxial growth (or deposition) process, as is defined above.

Additional ILD material 430 is formed above each top source/drain region 420. ILD material 430 may be composed of silicon dioxide, undoped silicate glass (USG), fluorosilicate glass (FSG), borophosphosilicate glass (BPSG), a spin-on low-κ dielectric layer, a chemical vapor deposition (CVD) low-κ dielectric layer or any combination thereof. The term “low-κ” as used throughout the present application denotes a dielectric material that has a dielectric constant of less than silicon dioxide. In another embodiment, a self-planarizing material such as a spin-on glass (SOG) or a spin-on low-κ dielectric material such as SiLK™ can be used as ILD material 430. The use of a self-planarizing dielectric material as ILD material 430 may avoid the need to perform a subsequent planarizing step.

In one embodiment, ILD material 430 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as ILD material 430, a planarization process or an etch back process follows the deposition of the dielectric material that provides ILD material 430. The planarization or etch back process may remove sacrificial dielectric cap 290 and upper portions of dielectric spacer material layer 330. As is shown in FIGS. 4A-4C, ILD material 430 that is present atop each top source/drain region 420 has a topmost surface that is coplanar to a topmost surface of dielectric spacer material layer 330.

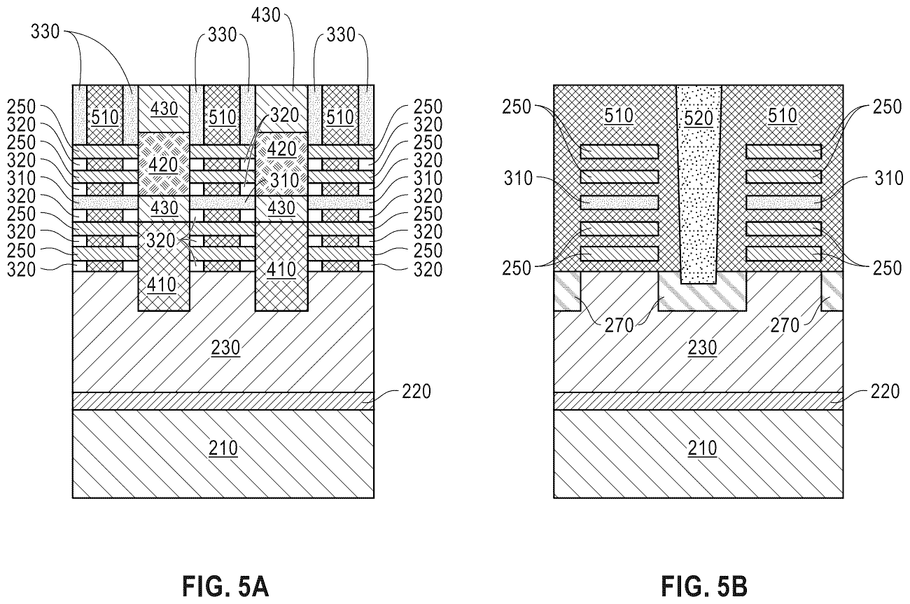

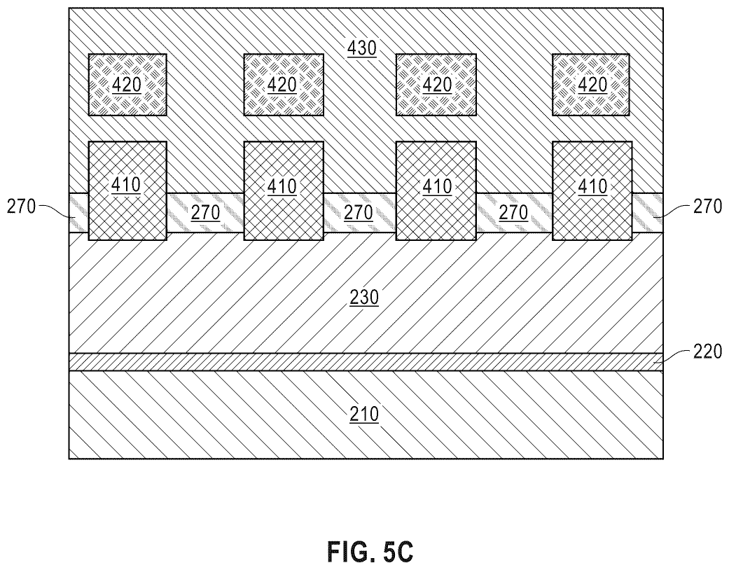

FIG. 5A depicts a cross-sectional view, of fabrication steps, along section line A of FIG. 1, FIG. 5B depicts a cross-sectional view along section line B of FIG. 1, and FIG. 5C depicts a cross-sectional view along section line C of FIG. 1. FIGS. 5A-5C depict the formation of gate cuts 520, the removal of sacrificial semiconductor material layer 240 and sacrificial gate structure 280, and the formation of a functional gate structure that is referred to as replacement gate 510.

Each sacrificial gate structure 280 is removed to provide a gate cavity for the FETs.

Next, each semiconductor channel material nanosheet (i.e., semiconductor channel material layer 250) of the FET is suspended by selectively etching each recessed sacrificial semiconductor material nanosheet (i.e., sacrificial semiconductor material layer 240) relative to each semiconductor channel material nanosheet (i.e., semiconductor channel material layer 250).

Functional gate structures are formed in each gate cavity. The functional gate structure surrounds a physically exposed surface of each semiconductor channel material nanosheet (i.e., semiconductor channel material layer 250). By “functional gate structure” it is meant a permanent gate structure used to control output current (i.e., flow of carriers in the channel) of a semiconducting device through electrical or magnetic fields. The functional gate structures are referred to as replacement gate 510 in the Figures.

While not depicted, in some embodiments, a gate dielectric portion may be present that includes a gate dielectric material. Such a gate dielectric portion may be an oxide, nitride, and/or oxynitride. In one example, the gate dielectric portion can be a high-κ material having a dielectric constant greater than silicon dioxide. Example high-κ dielectrics include, but are not limited to, HfO2, ZrO2, La2O3, Al2O3, TiO2, SrTiO3, LaAlO3, Y2O3, HfOxNy, ZrOxNy, La2OxNy, Al2OxNy, TiOxNy, SrTiOxNy, LaAlOxNy, Y2OxNy, SiON, SiNx, a silicate thereof, and an alloy thereof. Each value of x is independently from 0.5 to 3 and each value of y is independently from 0 to 2. In some embodiments, a multilayered gate dielectric structure comprising different gate dielectric materials, e.g., silicon dioxide, and a high-κ gate dielectric, can be formed and used as the gate dielectric portion.

The gate dielectric material used in providing a gate dielectric portion can be formed by any deposition process including, for example, chemical vapor deposition (CVD), plasma enhanced chemical vapor deposition (PECVD), physical vapor deposition (PVD), sputtering, or atomic layer deposition. In one embodiment of the present application, the gate dielectric material used in providing a gate dielectric portion can have a thickness in a range from one nm to ten nm. Other thicknesses that are lesser than, or greater than, the aforementioned thickness range can also be employed for the gate dielectric material that may provide a gate dielectric portion.

Replacement gate 510 may include a gate conductor material and a gate dielectric. The gate conductor material used in providing replacement gate 510 can include any conductive material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride, TiAlC, TiC, TiAl), an elemental metal silicide (e.g., tungsten silicide, nickel silicide, and titanium silicide), or multilayered combinations thereof. In one embodiment, replacement gate 510 may comprise an nFET gate metal. In another embodiment, replacement gate 510 may comprise a pFET gate metal. When multiple gate cavities are formed, it is possible to form a nFET in a first set of the gate cavities and wrapping around some of the semiconductor channel material nanosheet (i.e., semiconductor channel material layer 250) and a pFET in a second set of the gate cavities and wrapping around some of the semiconductor channel material nanosheet (i.e., semiconductor channel material layer 250).

The gate conductor material used in providing replacement gate 510 can be formed utilizing a deposition process including, for example, CVD, plasma enhanced chemical vapor deposition (PECVD), physical vapor deposition (PVD), sputtering, atomic layer deposition (ALD) or other like deposition processes. When a metal silicide is formed, a conventional silicidation process is employed. In one embodiment, the gate conductor material used in providing replacement gate 510 can have a thickness from five nm to two hundred nm. Other thicknesses that are lesser than, or greater than, the aforementioned thickness range can also be employed for the gate conductor material used in providing replacement gate 510.

In some embodiments, a functional gate structure (replacement gate 510) can be formed by providing a functional gate material stack of the gate dielectric material and the gate conductor material. A planarization process may follow the formation of the functional gate material stack.

Gate cuts 520 may be patterned by conventional lithography and etch processes to isolate the gate regions at cell boundaries. Each gate cut 520 is filled with a dielectric material such as, for example, SiN or a combination of SiN and SiO2.

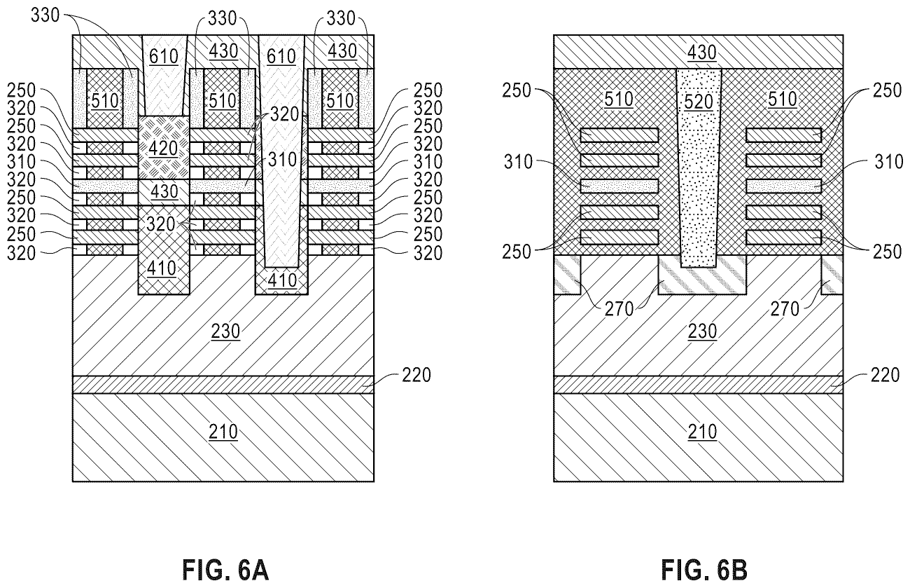

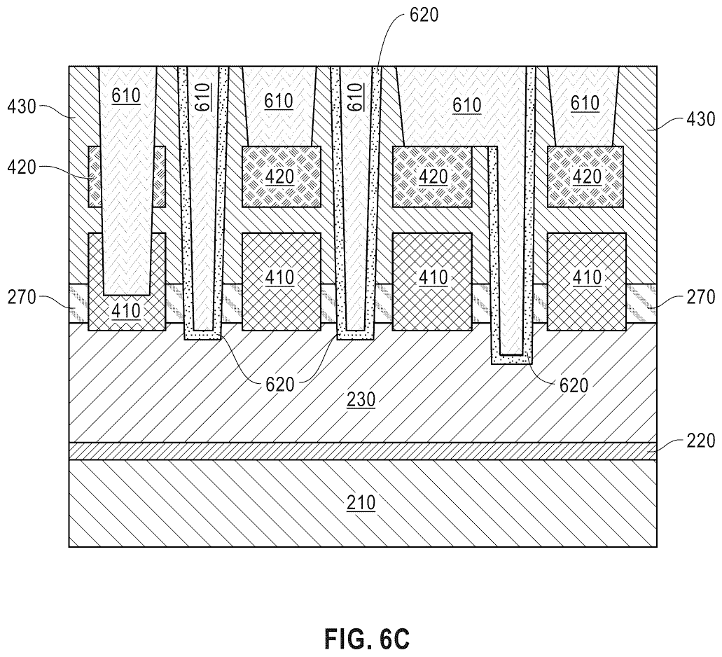

FIG. 6A depicts a cross-sectional view, of fabrication steps, along section line A of FIG. 1, FIG. 6B depicts a cross-sectional view along section line B of FIG. 1, and FIG. 6C depicts a cross-sectional view along section line C of FIG. 1. FIGS. 6A-6C depict the formation of contacts/vias 610 and via liners 620.

One or more trenches may be formed by lithography and an etching process, such as reactive-ion etching (RIE), laser ablation, or any etch process which can be used to selectively remove a portion of material such as ILD material 830. A hardmask (not shown) may be patterned using photoresist to expose areas of the device where trenches are desired and the hardmask may be utilized during the etching process in the creation of the trenches. The etching process only removes portions of the device not protected by the hardmask and the etching process stops at desired stopping points. In the embodiment depicted in FIGS. 6A-6C, there are a variety of trenches of different widths and depths stopping at, for example, bottom source/drain region 410, semiconductor layer 230, and upper source/drain region 420. In the depicted embodiment, three trenches extend to a depth that reaches semiconductor layer 230 and one of the trenches extends deeper into semiconductor layer 230 than the other two.

In some embodiments, subsequent to the formation of the trenches, any hardmasks that were utilized are removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

In some embodiments of the invention, via liners 620 can be formed between the vias that comprise contacts/vias 610 (e.g., the contacts/vias 610 that extend into semiconductor layer 230) and the surfaces of the formed trenches. Via liners 620 can serve as a dielectric barrier. Via liners 620 can be, for example, silicon nitride. In general, via liners 620 comprise any dielectric material, including, for example, a dielectric nitride, dielectric oxide, and/or dielectric oxynitride. More specifically, the via liners may be, for example, SiBCN, SiBN, SiOCN, SiON, SiCO, or SiC. In one example, the dielectric spacer material layer 330 is composed of a dielectric material such as SiO₂. In general, via liners 620 are composed of a different material than backside ILD 1010.

### The via liners 620 can be deposited by ALD, PVD, CVD, MOCVD, PECVD, or combinations thereof.

In general, contacts/vias 610 are formed and make contact with upper source/drain region 420, lower source/drain region 410 and/or semiconductor layer 230.

Contacts/vias 610 may each be formed by metal deposition and planarization. The metal layers comprise a silicide liner, such as, for example, Ti, Ni, or NiPt, followed by adhesion metal liner, such as, for example, TiN, and a conductive metal fill, such as, for example, Co, Ru, W, or Cu.

Contacts/vias 610 can be formed utilizing a deposition process including, for example, CVD, PECVD, physical vapor deposition (PVD), sputtering, atomic layer deposition (ALD) or other like deposition processes.

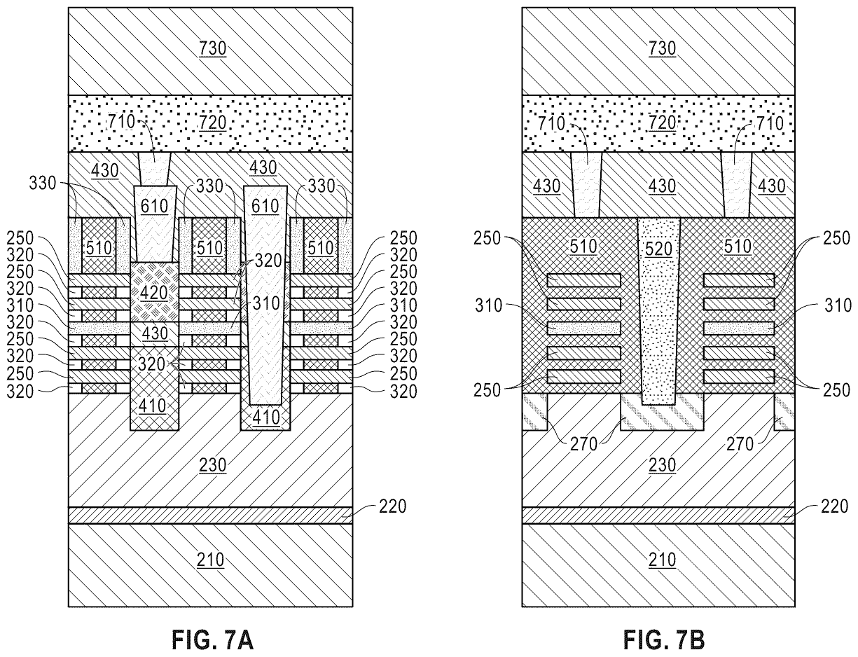

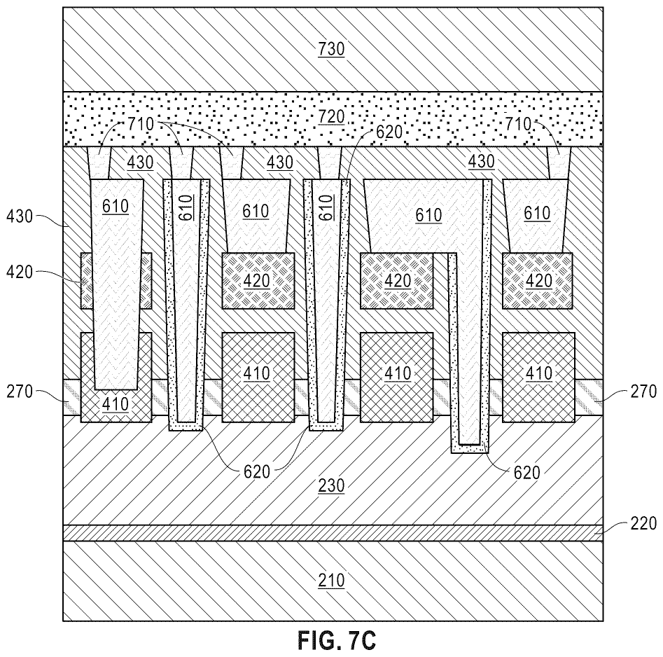

FIG. 7A depicts a cross-sectional view, of fabrication steps, along section line A of FIG. 1, FIG. 7B depicts a cross-sectional view along section line B of FIG. 1, and FIG. 7C depicts a cross-sectional view along section line C of FIG. 1. FIGS. 7A-7C depict the formation of BEOL contacts 710 in additional ILD material 430, BEOL interconnect 720, and the bonding of the device to carrier wafer 730.

Initially, an additional layer of ILD material 430 may be deposited on a top surface of the device in accordance with previously disclosed processes.

One or more trenches may be formed by lithography and an etching process, such as reactive-ion etching (RIE), laser ablation, or any etch process which can be used to selectively remove a portion of material such as ILD material 430. A hardmask (not shown) may be patterned using photoresist to expose areas of the device where trenches are desired and the hardmask may be utilized during the etching process in the creation of the trenches. The etching process only removes portions of the device not protected by the hardmask and the etching process stops at contacts/vias 610 and/or replacement gate 510.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

Frontside BEOL contacts 710 may be formed by, for example, depositing (e.g., by PVD), a metal layer (e.g., a thin adhesion TiN layer followed by bulk Cu, Co, or Ru fill) on exposed surfaces of replacement gate 820 or contacts/vias 610. Any deposition process may be used for the formation of the metal layer including, for example, chemical vapor deposition (CVD), plasma enhanced chemical vapor deposition (PECVD), physical vapor deposition (PVD), plating, sputtering, or atomic layer deposition. In other embodiments, co-evaporation techniques may be utilized to form BEOL contacts 710. In yet other embodiments, known sputter deposition or chemical vapor deposition techniques may be utilized to form the silicide layer.

In some embodiments, BEOL contacts 710 is deposited such that backside interconnects 1410 surround the silicide layer and fills the remaining area of the trench. Backside interconnects 1410 may be in direct contact with the silicide layer, replacement gate 820, or contacts/vias 610.

BEOL contacts 710 can include a conductive material including, for example, Cu, Co, Ru, W with a thin adhesion liner such as, for example, TiN.

BEOL contacts 710 can be formed utilizing a deposition process including, for example, plating, chemical vapor deposition (CVD), plasma enhanced chemical vapor deposition (PECVD), physical vapor deposition (PVD), sputtering, atomic layer deposition (ALD) or other like deposition processes.

BEOL interconnect 720 is depicted as a simple layer, rather than showing the specific interconnects. BEOL interconnect 720 may be formed according to processes known in the art such as, for example, patterning and dual damascene.

Carrier wafer 730 is a wafer that is bonded with a top surface of BEOL interconnect 720. Carrier wafer 730 may be, for example, a silicon wafer. Such bonding can be accomplished using fusion bonding (for example silicon oxide to silicon oxide) or by means of intermediate-layer bonding (for example using adhesives). A variety of bonding means may be used such as, for example, pressure bonding, for press-bonding the device to the carrier wafer 730 or a heat bonding approach for utilizing heat to bond the device to carrier wafer 730.

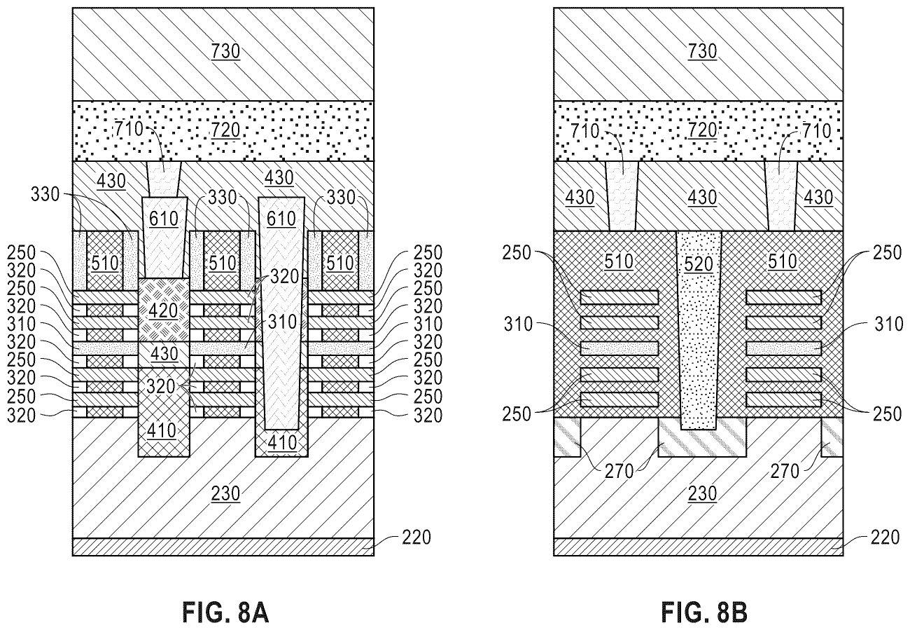

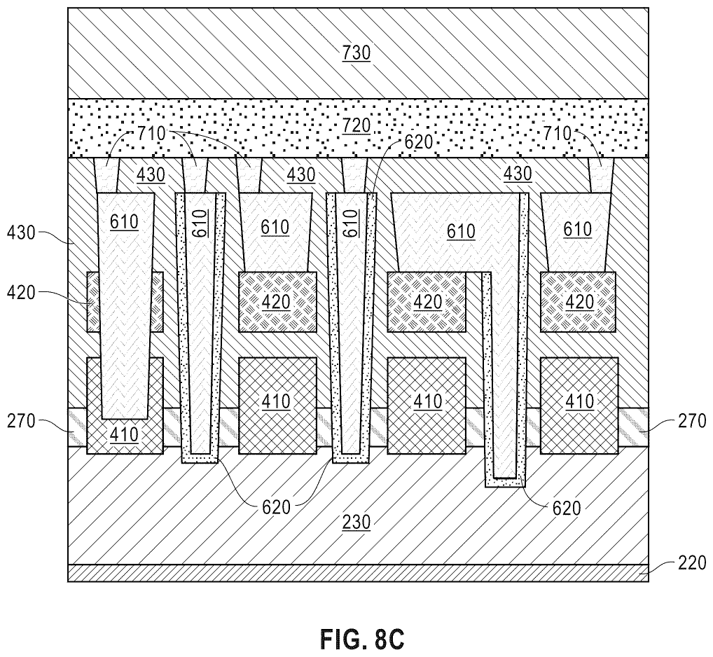

Subsequent to bonding the device to carrier wafer 730, the device is flipped upside-down such that the formation or removal of any layers occurs on what is considered to be the bottom of the device. This flip is not depicted in the Figures and, accordingly, FIGS. 8A-8C through FIGS. 14A-14C depict process steps that occur on the bottom surfaces of the device. In reality, during fabrication, these steps are performed when the device is upside-down, as compared to the depiction of FIGS. 8A-8C through FIGS. 14A-14C.

FIG. 8A depicts a cross-sectional view, of fabrication steps, along section line A of FIG. 1, FIG. 8B depicts a cross-sectional view along section line B of FIG. 1, and FIG. 8C depicts a cross-sectional view along section line C of FIG. 1. FIGS. 8A-8C depict the removal of semiconductor substrate 210.

As described above, prior to this step, the wafer containing device is flipped such that a top surface of the wafer faces downwards and the carrier wafer 730 acts as a bottom surface of the flipped device.

A combination of processes, such as wafer grinding, CMP, and/or wet/dry etch processes may be used to remove semiconductor substrate 210, stopping at etch stop layer 220.

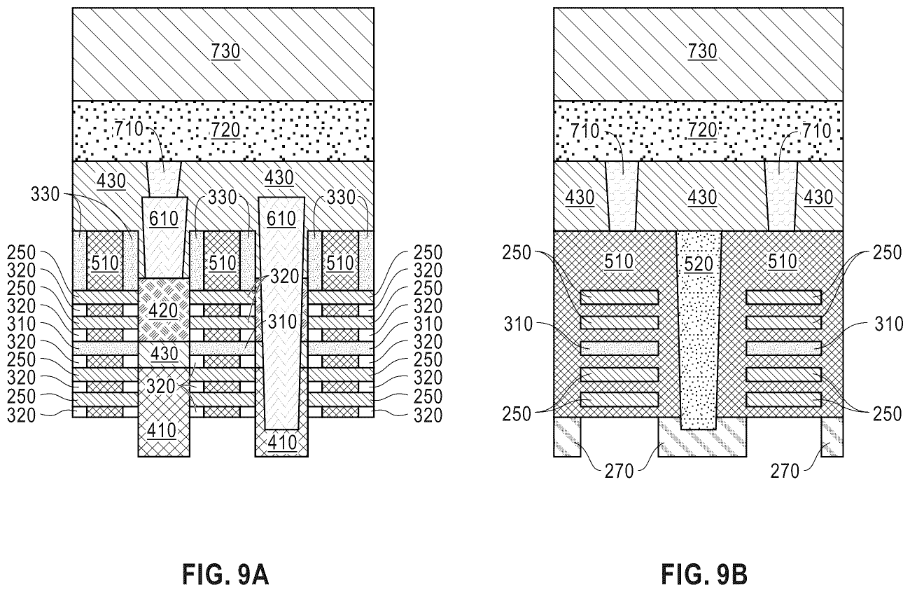

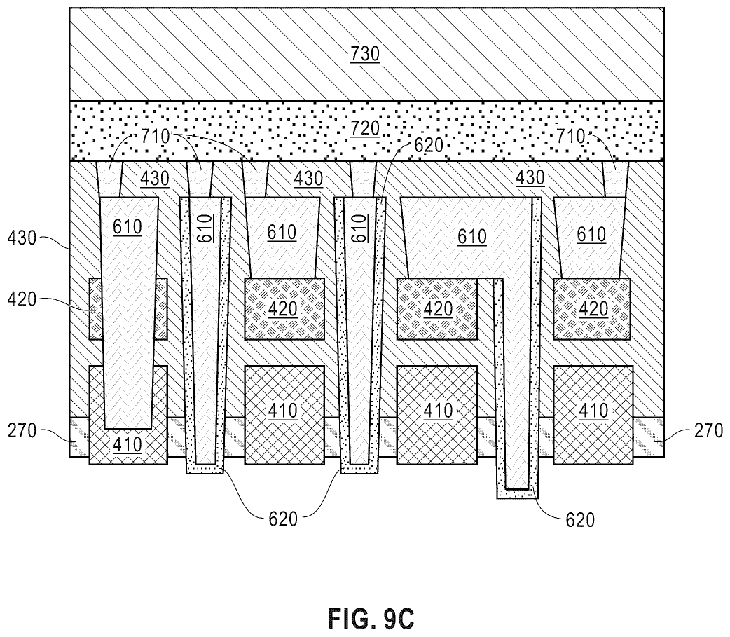

FIG. 9A depicts a cross-sectional view, of fabrication steps, along section line A of FIG. 1, FIG. 9B depicts a cross-sectional view along section line B of FIG. 1, and FIG. 9C depicts a cross-sectional view along section line C of FIG. 1. FIGS. 9A-9C depict the removal of etch stop layer 220 and semiconductor layer 230.

A selective wet or dry etch process is performed to remove etch stop layer 220.

Semiconductor layer 230 is removed using an etching process such as RIE, wet etch, or any etch process which can be used to selectively remove a portion of material, such as the semiconductor layer 230, with respect to STI layer 270, inner spacers 320, replacement gate 510, bottom source/drain region 410, and via liners 620. In some embodiments, such a process selectively removes silicon with respect to HfO2, SiN, and SiGe. In some embodiments, a backside ammonia wet etch is utilized. Embodiments of the present invention recognize that, in embodiments where each bottom source/drain region 410 comprises a silicon germanium alloy that is doped with a p-type dopant such as, for example, boron, there is not concern of damage to bottom source/drain region 410, even without a placeholder.

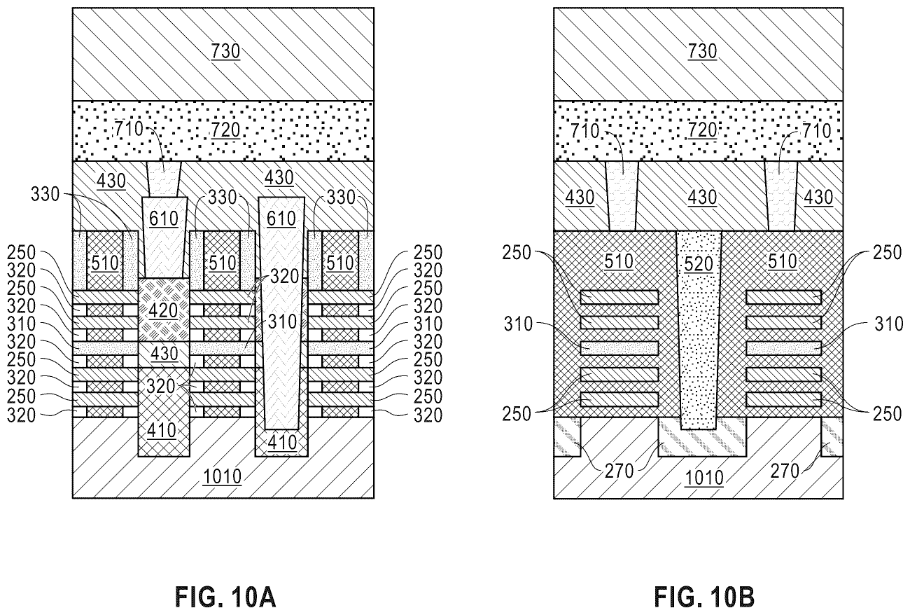

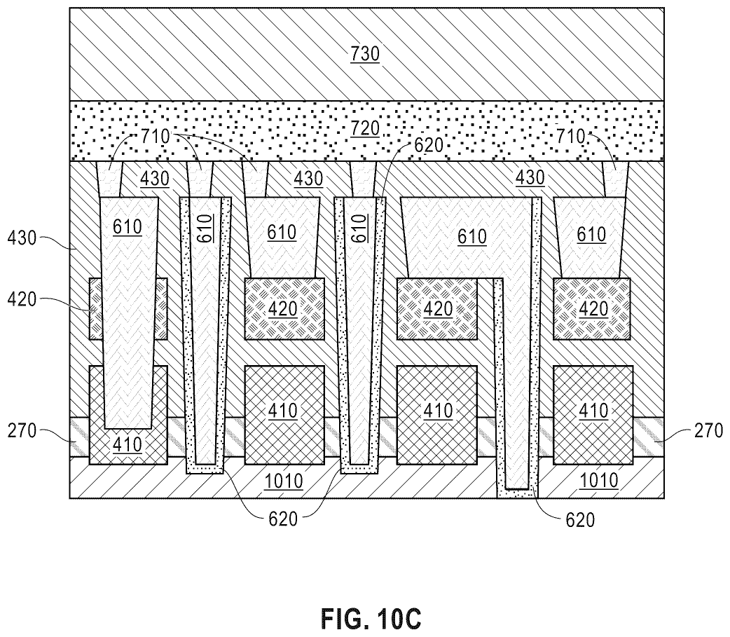

FIG. 10A depicts a cross-sectional view, of fabrication steps, along section line A of FIG. 1, FIG. 10B depicts a cross-sectional view along section line B of FIG. 1, and FIG. 10C depicts a cross-sectional view along section line C of FIG. 1. FIGS. 10A-10C depict the formation of backside ILD 1010.

Backside ILD 1010 material is formed on (under, as depicted) exposed surfaces of inner spacers 320, replacement gate 510 bottom source/drain region 410, STI layer 270, and via liners 620.

Backside ILD 1010 may be composed of silicon dioxide, undoped silicate glass (USG), fluorosilicate glass (FSG), borophosphosilicate glass (BPSG), a spin-on low-κ dielectric layer, a chemical vapor deposition (CVD) low-κ dielectric layer or any combination thereof. The term “low-κ” as used throughout the present application denotes a dielectric material that has a dielectric constant of less than silicon dioxide. In another embodiment, a self-planarizing material such as a spin-on glass (SOG) or a spin-on low-κ dielectric material such as SiLK™ can be used as backside ILD 1010. The use of a self-planarizing dielectric material as backside ILD 1010 may avoid the need to perform a subsequent planarizing step. In general, backside ILD 1010 is composed of a different material than STI layer 270 or via liners 620.

In one embodiment, backside ILD 1010 can be formed utilizing a deposition process including, for example, CVD, PECVD, evaporation or spin-on coating. In some embodiments, particularly when non-self-planarizing dielectric materials are used as backside ILD 1010, a planarization process, such as CMP, or an etch back process follows the deposition of the dielectric material that provides backside ILD 1010 such that the bottom surface of backside ILD 1010 is coplanar with the bottom surface (as depicted) of STI layer 270.

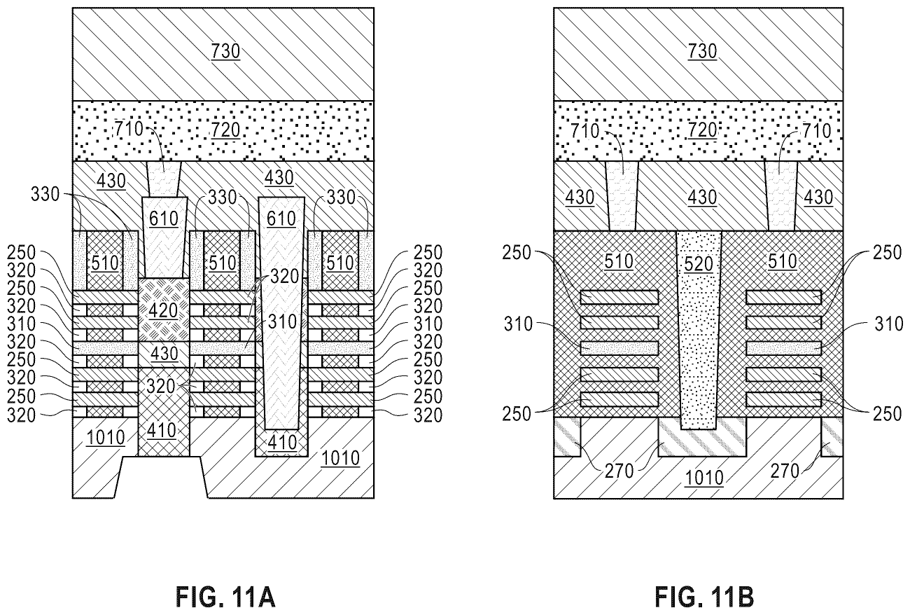

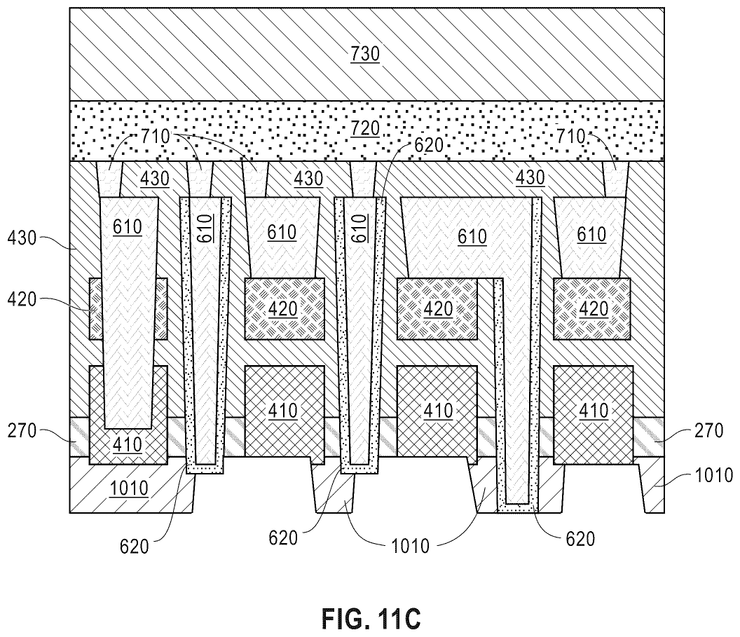

FIG. 11A depicts a cross-sectional view, of fabrication steps, along section line A of FIG. 1, FIG. 11B depicts a cross-sectional view along section line B of FIG. 1, and FIG. 11C depicts a cross-sectional view along section line C of FIG. 1. FIGS. 11A-11C depict an initial step of the backside contact trench formation.

A trench may be formed by an etching process such as RIE, laser ablation, or any etch process which can be used to selectively remove a portion of material such as backside ILD 1010. A hardmask (not shown) may be patterned using photoresist to expose areas where trenches are desired and the hardmask may be utilized during the etching process in the creation of the trenches. The etching process only removes portions of the device not protected by the hardmask and the etching process stops at bottom source/drain region 410 and via liners 620.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

As depicted in FIGS. 11A and 11C, the trenches are formed with respect to the bottom source/drain regions 410 that are not already contacted by contacts/vias 610.

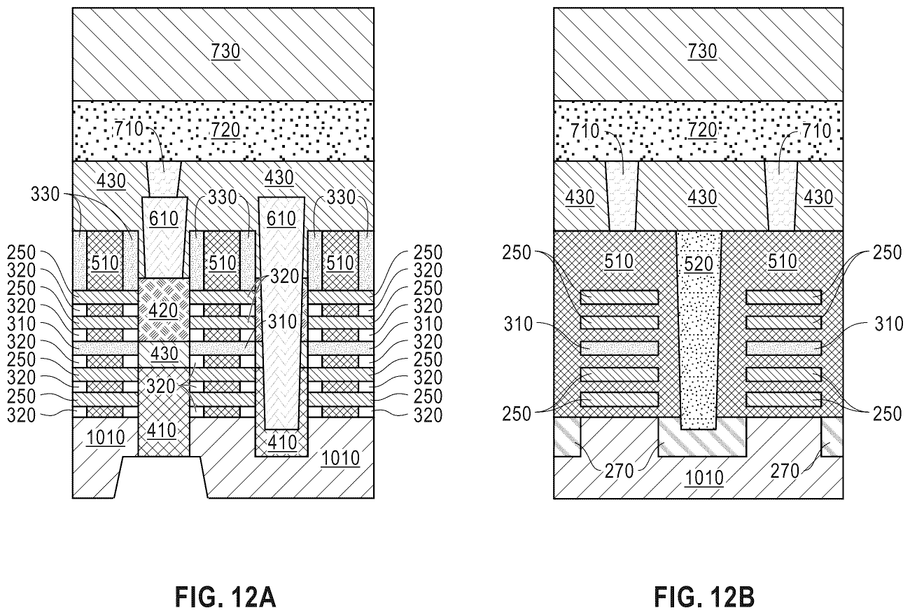

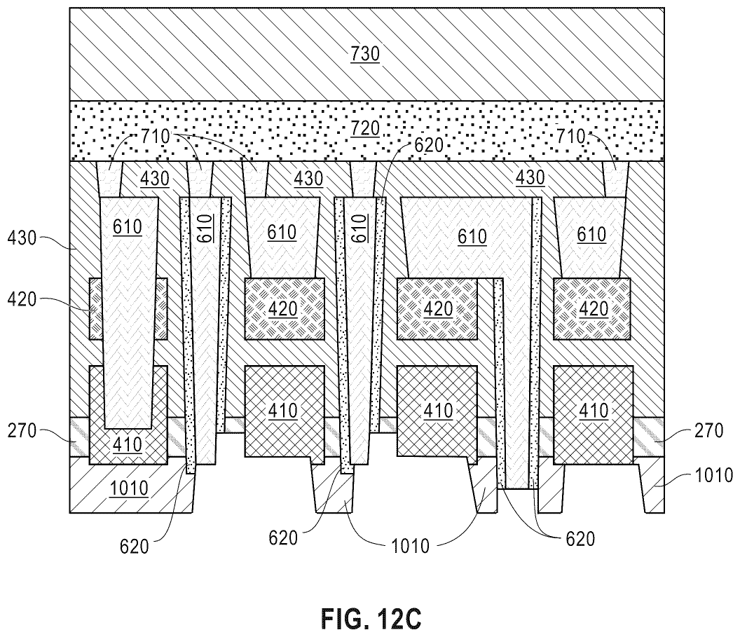

FIG. 12A depicts a cross-sectional view, of fabrication steps, along section line A of FIG. 1, FIG. 12B depicts a cross-sectional view along section line B of FIG. 1, and FIG. 12C depicts a cross-sectional view along section line C of FIG. 1. FIGS. 12A-12C depict the selective removal of the exposed portions of STI layer 270 and via liners 620.

The exposed portions of STI layer 270 and via liners 620 may be removed by an etching process, such as RIE, wet etch, or any etch process which can be used to selectively etch the STI layer 270 and via liners 620 relative to contacts/vias, backside ILD 1010, and bottom source/drain region 410.

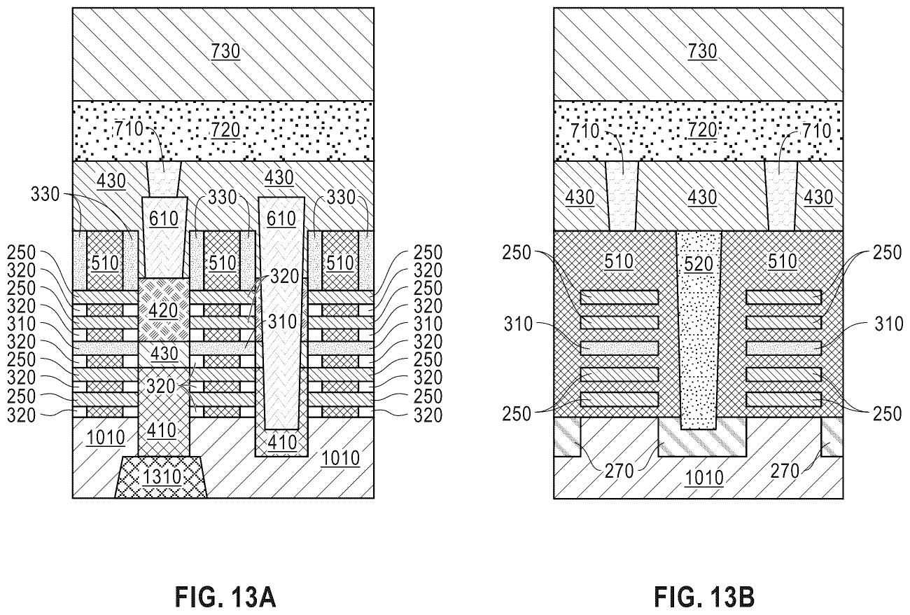

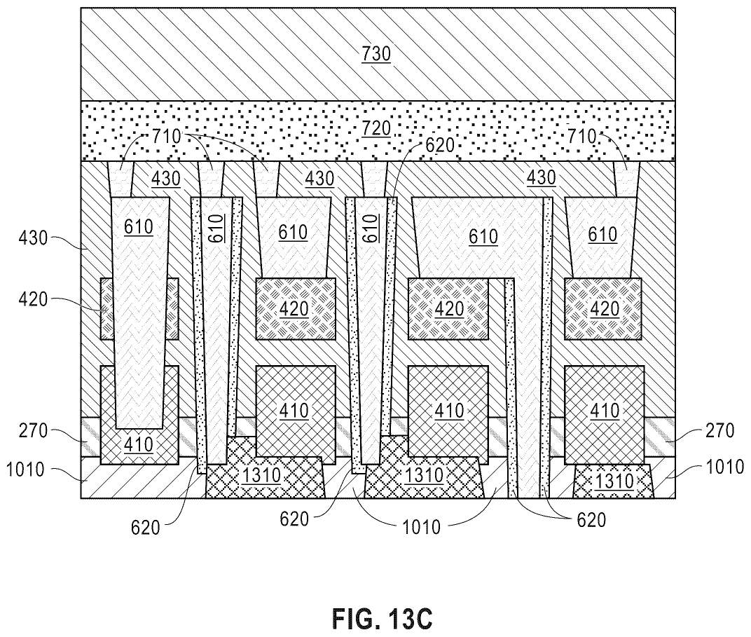

FIG. 13A depicts a cross-sectional view, of fabrication steps, along section line A of FIG. 1, FIG. 13B depicts a cross-sectional view along section line B of FIG. 1, and FIG. 13C depicts a cross-sectional view along section line C of FIG. 1. FIGS. 13A-13C depict the formation of backside contacts 1310.

In general, backside contacts 1810 are formed in the previously formed trenches (as discussed in reference to FIGS. 11A-11C though 12A-12C. Backside contacts 1310 make contact with bottom source/drain regions 410 not already in contact with contacts/vias 910.

Backside contacts 1310 may be formed by metal deposition and planarization. The metal layers comprise a silicide liner, such as, for example, Ti, Ni, or NiPt, followed by adhesion metal liner, such as, for example, TiN, and a conductive metal fill, such as, for example, Co, Ru, W, or Cu.

Backside contacts 1310 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

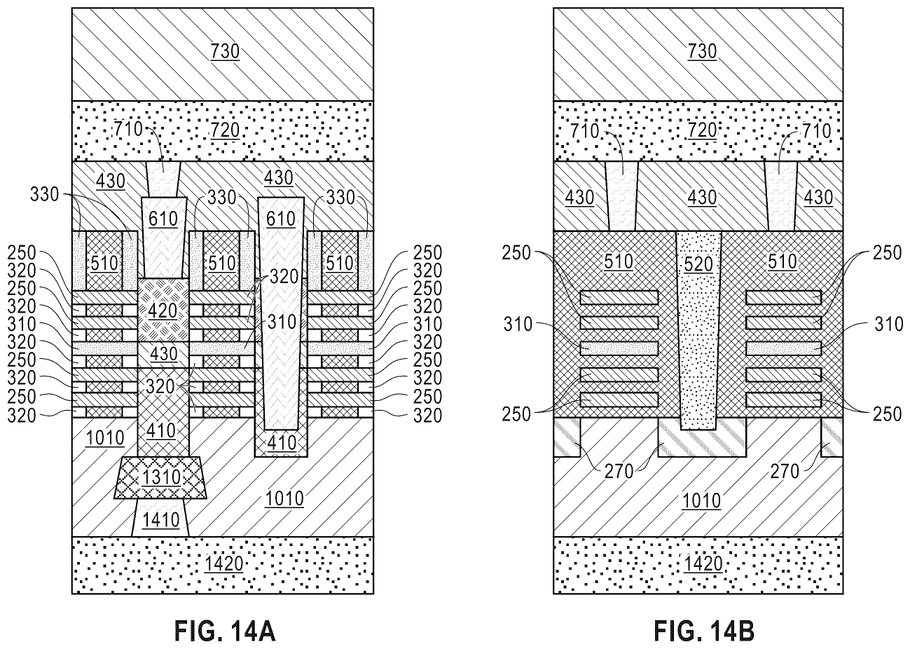

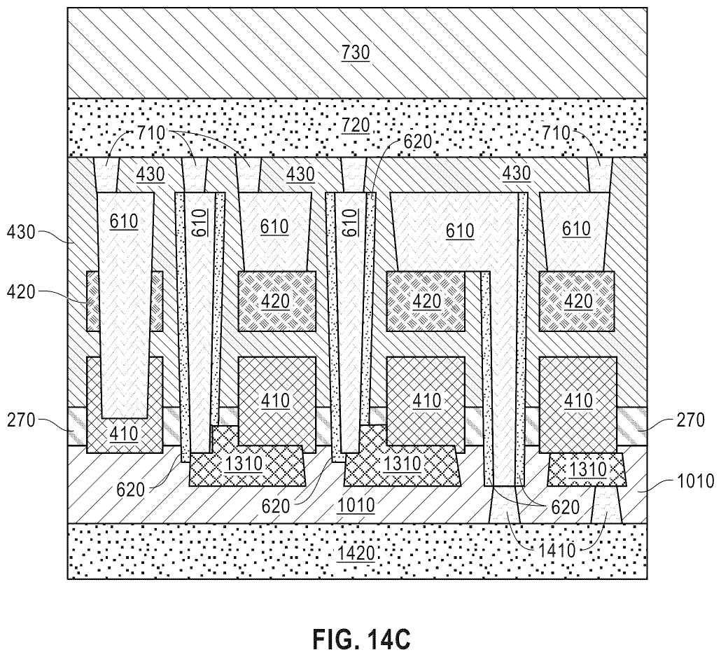

FIG. 14A depicts a cross-sectional view, of fabrication steps, along section line A of FIG. 1, FIG. 14B depicts a cross-sectional view along section line B of FIG. 1, and FIG. 14C depicts a cross-sectional view along section line C of FIG. 1. FIGS. 14A-14C depicts the formation of additional backside ILD 1010, backside interconnects 1410, and backside power delivery network (BSPDN) 1420.

Additional backside ILD 1010 material is formed beneath (as depicted) the already present backside ILD 1010 material and backside contacts 1310.

Backside ILD 1010 may be composed of silicon dioxide, undoped silicate glass (USG), fluorosilicate glass (FSG), borophosphosilicate glass (BPSG), a spin-on low-κ dielectric layer, a chemical vapor deposition (CVD) low-κ dielectric layer or any combination thereof. The term “low-κ” as used throughout the present application denotes a dielectric material that has a dielectric constant of less than silicon dioxide. In another embodiment, a self-planarizing material such as a spin-on glass (SOG) or a spin-on low-κ dielectric material such as SiLK™ can be used as backside ILD 1010. The use of a self-planarizing dielectric material as backside ILD 1010 may avoid the need to perform a subsequent planarizing step.

In one embodiment, backside ILD 1010 can be formed utilizing a deposition process including, for example, chemical vapor deposition (CVD), plasma enhanced chemical vapor deposition (PECVD), evaporation or spin-on coating. In some embodiments, particularly when non-self-planarizing dielectric materials are used as backside ILD 1010, a planarization process or an etch back process follows the deposition of the dielectric material that provides backside ILD 1010.

One or more trenches may be formed by an etching process, such as reactive-ion etching (RIE), laser ablation, or any etch process which can be used to remove a portion of material such as backside ILD 1010. A hardmask (not shown) may be patterned using photoresist to expose areas of backside ILD 1010 where trench(es) are desired and the hardmask may be utilized during the etching process in the creation of the trenches. The etching process only removes portions of backside ILD 1010 not protected by the hardmask, and the etching process stops coplanar to a bottom surface (as depicted) of either backside contacts 1310 or contacts/vias 610.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

Backside interconnects 1410 may be formed by, for example, depositing (e.g., by PVD), a metal layer (e.g., a thin adhesion TiN layer followed by bulk Cu, Co, or Ru fill) on exposed surfaces of backside contacts 1310 and contacts/vias 610. Any deposition process may be used for the formation of the metal layer including, for example, chemical vapor deposition (CVD), plasma enhanced chemical vapor deposition (PECVD), physical vapor deposition (PVD), plating, sputtering, or atomic layer deposition. In other embodiments, co-evaporation techniques may be utilized to form backside interconnects 1410. In yet other embodiments, known sputter deposition or chemical vapor deposition techniques may be utilized to form the silicide layer.

In some embodiments, backside interconnects 1410 are deposited such that backside interconnects 1410 surround the silicide layer and fills the remaining area of the trench. Backside interconnects 1410 may be in direct contact with the silicide layer, backside contact 1310, contacts/vias 610, and/or backside ILD 1010.

Backside interconnects 1410 can include a conductive material including, for example, Cu, Co, Ru, W with a thin adhesion liner such as, for example, TiN.

Backside interconnects 1410 can be formed utilizing a deposition process including, for example, plating, chemical vapor deposition (CVD), plasma enhanced chemical vapor deposition (PECVD), physical vapor deposition (PVD), sputtering, atomic layer deposition (ALD) or other like deposition processes.

In general, backside interconnects 1410 make contact with (i) a backside contact 1310 that is contacting a bottom source/drain region 410 that is not already contacted by contacts/vias 610 and contacts/vias 610 that are contacting an upper source/drain region 420 that is not already contacted by a BEOL contact 710.

BSPDN 1420 comprises a backside power delivery network that is depicted as a simplified layer. BSPDN 1420 may be formed according to processes known in the art.

Subsequent to the formation of BSPDN 1420, the wafer may be released from carrier wafer 730 and flipped over (original flip which was discussed in reference to FIGS. 8A-8C was never depicted) such that BSPDN 1420 is on the bottom of the wafer and operates as a backside power delivery network. Alternatively, the carrier wafer 730 is kept, and through-silicon vias (TSVs) can be formed form backside of the wafer to BEOL interconnect at frontside.

The resulting semiconductor structure includes at least one transistor stacking over another transistor, where the bottom transistor is pFET with a SiGe based source/drain region (bottom source/drain region 410) that is deeper than the gate (replacement gate 510). The resulting semiconductor structure may further include a backside contact (backside contacts 1310) that connects to the pFET source/drain region (bottom source/drain region 410), partially wraps around a sidewall of the pFET source/drain region (bottom source/drain region 410), and connects to a deep via (contacts/vias 610).

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a first field-effect transistor (FET) having a first source/drain region, wherein a bottom surface of the first source/drain region is of a depth lower than a bottom surface of a gate region;
a second FET stacked above the first FET;
a first via, wherein the first via has a top surface above a top surface of the second FET; and
a backside contact contacting the first source/drain region and the first via.

2. The semiconductor structure of claim 1, wherein the first source/drain region comprises a silicon germanium alloy doped with a p-type dopant.

3. The semiconductor structure of claim 2, wherein the p-type dopant is boron.

4. The semiconductor structure of claim 1, further comprising:
a first frontside contact contacting a second source/drain region of the second FET; and
a second via contacting the first frontside contact, wherein the second via has a bottom surface below the bottom surface of the first source/drain region.

5. The semiconductor structure of claim 1, wherein the first via is shorter than the second via.

6. The semiconductor structure of claim 1, wherein the first source/drain region is electrically connected to a back end of line (BEOL) interconnect.

7. The semiconductor structure of claim 4, wherein the second source/drain region is electrically connected to a backside interconnect.

8. The semiconductor structure of claim 1, wherein the first via has a dielectric liner.

9. The semiconductor structure of claim 8, further comprising a backside interlayer dielectric (ILD), wherein the backside ILD is of a material different than: (i) the dielectric liner and (ii) a shallow trench isolation layer.

10. The semiconductor structure of claim 9, wherein the shallow trench isolation layer has a height between fifteen and thirty nanometers.

11. The semiconductor structure of claim 4, wherein the second source/drain region comprises a silicon alloy that is doped with an n-type dopant.

12. The semiconductor structure of claim 11, wherein the n-type dopant is phosphorous.

13. The semiconductor structure of claim 6, further comprising a carrier wafer contacting the BEOL interconnect.

14. The semiconductor structure of claim 1, wherein the gate region wraps around nanosheet stacks of semiconductor channel material layers present within each of the first FET and the second FET.

15. The semiconductor structure of claim 6, wherein the gate region is electrically connected to the BEOL interconnect through a second frontside contact.

16. The semiconductor structure of claim 4, further comprising an inner spacer layer contacting the gate region and a selection from the group consisting of: (i) the first source/drain region and (ii) the second source/drain region.

17. A semiconductor structure comprising:
a bottom field-effect transistor (FET) having a source/drain region, wherein:
a bottom surface of the source/drain region is of a depth lower than a bottom surface of a gate region; and
the source/drain region comprises epitaxially grown silicon with added dopants;
a top FET;
a via having a top surface above a top surface of the top FET; and
a backside contact contacting the source/drain region and the via.

18. The semiconductor structure of claim 17, wherein the source/drain region is electrically connected to a back end of line (BEOL) interconnect.

19. The semiconductor structure of claim 17, further comprising:
a frontside contact contacting a second source/drain region of the top FET; and
a second via contacting the frontside contact, wherein the second via has a bottom surface below the bottom surface of the source/drain region.

20. A method of forming a semiconductor structure, the method comprising:
forming a p-channel field-effect transistor (pFET) having a source/drain region, wherein:
a bottom surface of the source/drain region is of a depth lower than a bottom surface of a gate region; and
the source/drain region comprises a silicon germanium alloy doped with boron;
forming an n-channel field-effect transistor (nFET);
forming a via, wherein the via has a top surface above a top surface of the nFET;
flipping the semiconductor structure;
selectively removing a substrate respective to the source/drain region;
forming a backside interlayer dielectric (ILD), wherein the backside ILD is of a different material than a shallow trench isolation layer; and
forming a backside contact, wherein the backside contact contacts the source/drain region and the via.
